(19) United States
(12) Patent Application Publication
(10) Pub. No.: US 2026/0271224 A1
(43) Pub. Date: Sep. 10, 2026

(54) COOLING UNIT AND COOLING SYSTEM

(71) Applicant: NIDEC CORPORATION, Kyoto (JP)

(72) Inventors: Keisuke KAWATA, Kyoto (JP); Toshihiko TOKESHI, Kyoto (JP); Takehito TAMAOKA, Kyoto (JP)

(21) Appl. No.: 18/869,481

(22) PCT Filed: May 26, 2023
(86) PCT No.: PCT/JP2023/019661

§ 371 Date: Nov. 26, 2024

(30) Foreign Application Priority Data
May 27, 2022 (JP) 2022-087048
Feb. 27, 2023 (JP) 2023-028444

(51) Int. Cl. H05K 7/20

(52) U.S. Cl. CPC H05K 7/20254; H05K 7/20263; H05K 7/20272

(57) ABSTRACT

A cooling assembly includes a first cold plate and a second cold plate, an inflow pipe, and an outflow pipe. The first cold plate and the second cold plate are provided on respective sides of a heat generating component in a first direction. The inflow pipe allows the refrigerant to flow into the first cold plate and the second cold plate. The refrigerant flowing out of the first cold plate and the second cold plate passes through the outflow pipe. At least a portion of the first cold plate and at least a portion of the second cold plate overlap each other in the first direction. At least a portion of the inflow pipe and at least a portion of the outflow pipe are located between the first cold plate and the second cold plate in the first direction.

### CROSS REFERENCE TO RELATED APPLICATION

This is a U.S. national stage of application No. PCT/JP 2023/019661, filed on May 26, 2023, with priority under 35 U.S.C. § 119(a) and 35 U.S.C. § 365(b) being claimed from Japanese Application No. 2022-087048, filed on May 27, 2022, and Japanese Application No. 2023-028444, filed on Feb. 27, 2023, the disclosures of which are hereby incorporated herein by reference.

### 1. FIELD OF THE INVENTION

The present disclosure relates to cooling assemblies and cooling systems.

### 2. BACKGROUND

Conventionally, there has been known a cooling assembly including a cold plate disposed on a heat generating component, an inflow pipe through which refrigerant flows into the cold plate, and an outflow pipe through which the refrigerant flowing out of the cold plate passes (see, for example, JP 2008-218589 A).

JP 2008-218589 A describes a cooling device including a heat receiving member disposed on a heating element. The heat receiving member has a structure in which two members, that is, a base member and a case member, are combined and joined to form a sealed space through which the refrigerant passes. The base member is disposed on the heating element. The case member is disposed on the base member. The case member is provided with an inflow path port through which the refrigerant flows into the sealed space and an outflow path port through which the refrigerant flowing out of the sealed space passes.

In the cooling device of JP 2008-218589 A, the inflow path port and the outflow path port are disposed in the case member. Therefore, since the cooling device of JP 2008-218589 A is configured to cool the heating element only from above, it is difficult to efficiently cool the heating element.

### SUMMARY

The present disclosure has been made in view of the above problem, and example embodiments provide cooling assemblies and cooling systems each capable of efficiently cooling a heat generating component.

An example embodiment of a cooling assembly of the present disclosure includes a first cold plate and a second cold plate, an inflow pipe, and an outflow pipe. The first cold plate and the second cold plate are provided on respective sides of a heat generating component in a first direction. The inflow pipe allows a refrigerant to flow into the first cold plate and the second cold plate. The refrigerant flowing out of the first cold plate and the second cold plate passes through the outflow pipe. At least a portion of the first cold plate and at least a portion of the second cold plate overlap each other in the first direction. At least a portion of the inflow pipe and at least a portion of the outflow pipe are located between the first cold plate and the second cold plate in the first direction.

An example embodiment of a cooling system of the present disclosure includes the cooling assembly described above, a pump assembly, and a heat exchanger. The pump assembly causes the refrigerant to flow through the cooling assembly. The heat exchanger cools the refrigerant flowing from the cooling assembly. The cooling assembly, the pump assembly, and the heat exchanger are connected to each other by a connection pipe. The refrigerant circulates through the cooling assembly, the pump assembly, and the heat exchanger.

An example embodiment of a cooling assembly of the present disclosure includes a third cold plate, an inflow pipe, an outflow pipe, and a fifth connection portion. The third cold plate is provided on one side of the heat generating component in the first direction. The inflow pipe allows the refrigerant to flow into the third cold plate. The refrigerant flowing out of the third cold plate passes through the outflow pipe. The fifth connection portion is connected to the inflow pipe or the outflow pipe and fixed to the third cold plate. The fifth connection portion is movable with respect to the inflow pipe or the outflow pipe.

According to the example embodiments of the present disclosure, it is possible to provide cooling assemblies and cooling systems each capable of efficiently cooling a heat generating component.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic diagram illustrating a cooling system including a cooling assembly according to a first example embodiment of the present disclosure.

FIG. 2 is a perspective view illustrating a periphery of a cooling assembly according to an example embodiment of the present disclosure.

FIG. 3 is a perspective view illustrating structures of a cold plate, an inflow pipe, and an outflow pipe of a cooling assembly according to an example embodiment of the present disclosure.

FIG. 4 is an exploded perspective view illustrating structures of a cold plate, an inflow pipe, and an outflow pipe of a cooling assembly according to an example embodiment of the present disclosure.

FIG. 5 is an exploded perspective view illustrating a cold plate, a heat conductor, and a first heat generating component of a cooling assembly according to an example embodiment of the present disclosure.

FIG. 6 is an exploded perspective view illustrating a cold plate, a heat conductor, and a first heat generating component of a cooling assembly according to an example embodiment of the present disclosure.

FIG. 7 is an exploded perspective view illustrating a structure of a cold plate of a cooling assembly according to an example embodiment of the present disclosure.

FIG. 8 is an exploded perspective view illustrating a structure of a cold plate of a cooling assembly according to an example embodiment of the present disclosure.

FIG. 9 is a diagram illustrating a structure of a second member of a cold plate of a cooling assembly according to an example embodiment of the present disclosure from the other side in a first direction.

FIG. 10 is a cross-sectional view of the cold plate, the heat conductor, and the first heat generating component of the cooling assembly taken along line X-X in FIG. 9.

FIG. 11 is a cross-sectional view of the cold plate, the heat conductor, and the first heat generating component of the cooling assembly taken along line XI-XI in FIG. 9.

FIG. 12 is a diagram illustrating a positional relationship between a heat conductor of the cooling assembly and an internal flow path.

FIG. 13 is a perspective view illustrating a structure of a cooling assembly according to a first modification of the first example embodiment.

FIG. 14 is a perspective view illustrating a structure of a cooling assembly U1A according to a second modification of the first example embodiment.

FIG. 15 is an exploded perspective view illustrating a structure of the cooling assembly U1A according to the second modification of the first example embodiment.

FIG. 16 is a cross-sectional view of the cooling assembly U1A according to the second modification of the first example embodiment.

FIG. 17 is a cross-sectional view of the cooling assembly U1A according to the second modification of the first example embodiment.

FIG. 18 is a diagram illustrating an outline of a cooling system 101 including a cooling assembly U1B according to a second example embodiment of the present disclosure.

FIG. 19 is a perspective view illustrating the cooling assembly UlB.

FIG. 20 is a cross-sectional view illustrating structures of an inflow pipe 110 and an outflow pipe 120.

FIG. 21 is a diagram illustrating the cooling assembly U1B in which a cold plate P3 is located at a first position T1.

FIG. 22 is a diagram illustrating the cooling assembly U1B in which the cold plate P3 is located at a second position T2.

### DETAILED DESCRIPTION

### First Example Embodiment

Hereinafter, a first example embodiment of the present disclosure will be described with reference to the drawings. In the drawings, the identical or corresponding parts will be denoted by the identical reference signs, and the description of such parts will not be repeated.

The present description appropriately describes a first direction Z, a second direction X, and a third direction Y orthogonal to one another for easy understanding. One side in the first direction Z is referred to as one side Z1 in the first direction Z, and the other side in the first direction Z is referred to as the other side Z2 in the first direction Z. One side in the second direction X is referred to as one side X1 in the second direction X, and the other side in the second direction X is referred to as the other side X2 in the second direction X. One side in the third direction Y is referred to as one side Y1 in the third direction Y, and the other side in the third direction Y is referred to as the other side Y2 in the third direction Y. However, the directions are defined merely for convenience of explanation, and the orientations of the exemplary cold plate of the present disclosure in use are not limited unless the horizontal direction and the vertical direction need to be defined in particular. In the present description, the “orthogonal direction” includes a substantially orthogonal direction.

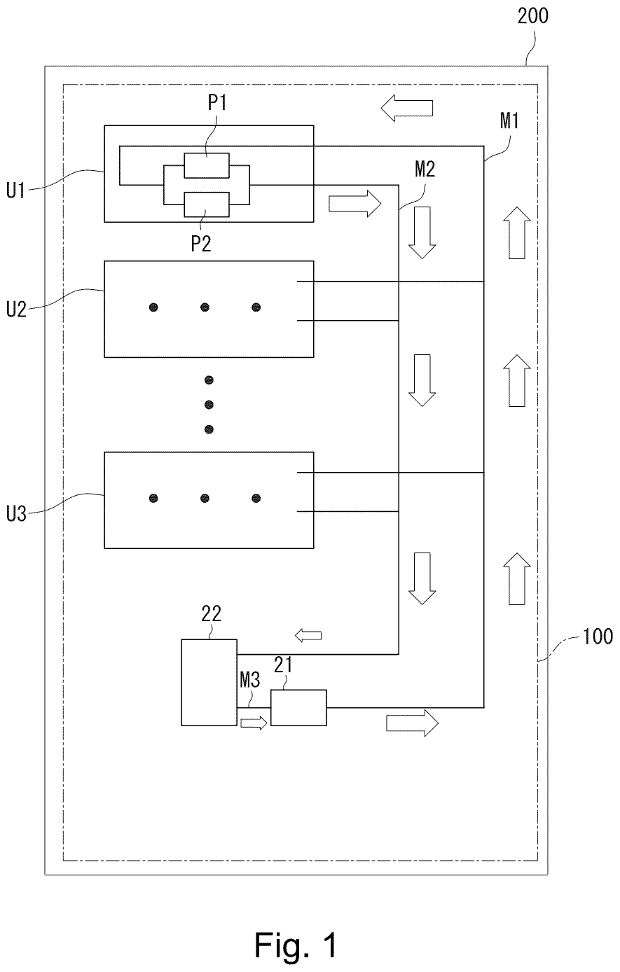

Cooling assemblies U1, U2, and U3 each having cold plates P1 and P2 according to the first example embodiment of the present disclosure will be described with reference to FIGS. 1 to 12. First, with reference to FIG. 1, a cooling system 100 having the cooling assemblies U1, U2, and U3 according to the first example embodiment of the present disclosure will be described. FIG. 1 is a diagram illustrating the overview of the cooling system 100 having the cooling assemblies U1, U2, and U3 according to the first example embodiment of the present disclosure.

The cooling system 100 is provided in, for example, a computer device 200 and cools the computer device. 200 The computer device 200 is an example of electronic equipment. As an example, the cooling system 100 includes three cooling assemblies U1, U2, and U3, a manifold M1, a manifold M2, a pump assembly 21, and a heat exchanger 22. The cooling system 100 may be provided to other than the computer device 200.

The pump assembly 21 includes, for example, one or a plurality of pump devices. The plurality of pump devices is connected to each other in series or in parallel. Each of the pump devices has one or a plurality of pumps that sucks the refrigerant and discharges the refrigerant. The plurality of pumps is connected to each other in series or in parallel. The refrigerant may be a coolant such as cooling water or cooling oil, or may be a cooling gas. In the present example embodiment, the refrigerant is, for example, a coolant.

The pump assembly 21 is connected to, for example, the manifold M1, and the manifold M2 via a flow path M3 and the heat exchanger 22. The manifold M1 is a pipe that connects, for example, the pump assembly 21 and the cooling assemblies U1, U2, and U3. The flow path M3 is a pipe that connects, for example, the pump assembly 21 and the heat exchanger 22. The refrigerant passes through the inside of the manifolds M1 and M2 and the flow path M3.

The pump assembly 21 causes the refrigerant to flow through the cooling assemblies U1, U2, and U3. Specifically, the pump assembly 21 supplies the refrigerant to the manifold M1. The refrigerant passes through the inside of the manifold M1. The manifold M1 distributes and supplies, to the cooling assemblies U1, U2, and U3, the refrigerant supplied from the pump assembly 21. The refrigerants supplied to the cooling assemblies U1, U2, and U3 pass through the cooling assemblies U1, U2, and U3, respectively, and are supplied to the manifold M2. Hereinafter, the cooling assembly U1 will be representatively described. The configurations and functions of the cooling assemblies U2 and U3 are the same as those of the cooling assembly U1.

The cooling assembly U1 includes, for example, two cold plates P1 and P2. Each of the cold plates P1 and P2 receives heat from a heat generating component 500 to be described later and cools the heat generating component 500. The heat generating component 500 is, for example, an arithmetic device such as a CPU arranged in the computer device 200, a storage device such as a memory, and the like. The refrigerant passes through the cold plates P1 and P2 when passing through the inside of the cooling assembly U1. For example, the refrigerant exchanges heat in the cold plates P1 and P2, whereby the refrigerant having heat circulates in the cooling system 100. The cold plates P1 and P2 may be cold plates having the same structure or cold plates having different structures. The cooling assembly U1 may include three or more cold plates including the cold plates P1 and P2.

The manifold M2 is a pipe that connects, for example, the cooling assemblies U1, U2, and U3 and the heat exchanger 22. The refrigerant passes through the inside of the manifold M2. The manifold M2 joins and supplies, to the heat exchanger 22, the refrigerant that has passed through each of the cooling assemblies U1, U2, and U3. The refrigerant supplied to the heat exchanger 22 passes through the heat exchanger 22, for example. The heat exchanger 22 cools the refrigerant flowing from the cooling assemblies U1, U2, and U3. For example, the heat exchanger 22 is a radiator that radiates heat to the outside when a refrigerant having heat passes therethrough. The heat exchanger 22 includes, inside thereof, a plurality of refrigerant pipes through which the refrigerant passes inside thereof, and a plurality of fins arranged around the refrigerant pipes. A part of each of the plurality of fins is in contact with the refrigerant pipe. More specifically, the fin and the refrigerant pipe are joined by welding or the like. The fins absorb heat of the refrigerant pipe and the refrigerant and radiate the heat to the outside air, thereby lowering the temperature of the refrigerant. However, the heat exchanger 22 is not limited to a radiator that radiates heat to the outside. The heat exchanger 22 may exchange heat with, for example, a flow path through which another refrigerant passes.

The refrigerant having passed through the heat exchanger 22 passes through the flow path M3 and is supplied to the pump assembly 21. The refrigerant supplied to the pump assembly 21 is again supplied to the manifold M1 by the pump assembly 21. As described above, the refrigerant circulates through the cooling assemblies U1, U2, and U3, the pump assembly 21, and the heat exchanger 22. In the present example embodiment, in the cooling system 100, the refrigerant circulates through the pump assembly 21, the manifold M1, the cooling assemblies U1, U2, and U3, the manifold M2, the heat exchanger 22, and the flow path M3. In FIG. 1, the circulation of the refrigerant is indicated by arrows. The refrigerant may circulate in opposite directions. The arrangement of the cooling assemblies U1, U2, and U3, the pump assembly 21, and the heat exchanger 22 is merely an example, and other arrangements may be adopted.

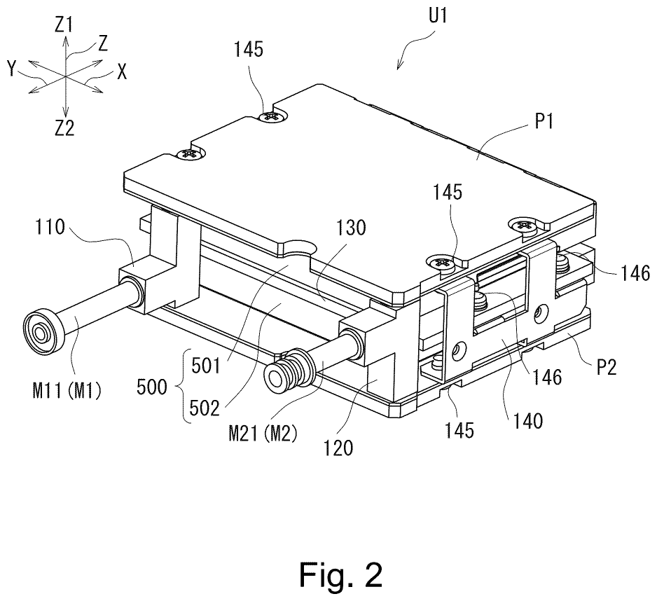

Next, the cooling assembly U1 including the cold plate P1 will be described in detail with reference to FIG. 2. FIG. 2 is a perspective view illustrating the periphery of the cooling assembly U1.

As illustrated in FIG. 2, the cooling assembly U1 includes the cold plate P1, the cold plate P2, an inflow pipe 110, and an outflow pipe 120. The cold plate P1 is an example of a “first cold plate” according to the present disclosure, and the cold plate P2 is an example of a “second cold plate” according to the present disclosure. The cold plate P1 and the cold plate P2 are provided on respective sides of the heat generating component 500 in the first direction Z. The inflow pipe 110 allows the refrigerant to flow into the cold plate P1 and the cold plate P2. The refrigerant flowing out of the cold plate P1 and the cold plate P2 passes through the outflow pipe 120. A connection pipe M11 constituting a part of the manifold M1 is connected to the inflow pipe 110. A connection pipe M21 constituting a part of the manifold M2 is connected to the outflow pipe 120.

As described above, the cold plate P1 and the cold plate P2 are provided on respective sides of the heat generating component 500 in the first direction Z. Therefore, since the heat generating component 500 can be cooled from both sides, the heat generating component 500 can be efficiently cooled.

The refrigerant having passed through the connection pipe M11 flows into the cold plate P1 and the cold plate P2 via the inflow pipe 110. The refrigerant that has passed through the cold plate P1 and the cold plate P2 flows out to the connection pipe M21 via the outflow pipe 120. The refrigerant absorbs heat from the heat generating component 500 when passing through the cold plate P1 and the cold plate P2. This suppresses an increase in the temperature of the heat generating component 500.

The heat generating component 500 may include only one heat generating component, or may include a plurality of heat generating components. In the present example embodiment, the heat generating component 500 includes two heat generating components (a first heat generating component 501 and a second heat generating component 502). The first heat generating component 501 and the second heat generating component 502 are stacked in the first direction Z. In the present example embodiment, the cooling assembly U1 further includes a support member 130. The support member 130 is located between the first heat generating component 501 and the second heat generating component 502. The support member 130 Supports the first heat generating component 501 and the second heat generating component 502. The first heat generating component 501 and the second heat generating component 502 may be fixed at predetermined positions on the support member 130. The support member 130 has a flat plate shape. The support member 130 is formed of, for example, a metal plate, but not particularly limited thereto. In the present example embodiment, an example in which the support member 130 is located between the first heat generating component 501 and the second heat generating component 502 is described, but the support member 130 may not be located between the first heat generating component 501 and the second heat generating component 502.

In the present example embodiment, the cooling assembly U1 further includes a fixing member 140. The fixing members 140 are disposed, for example, on respective sides of the cold plates P1 and P2 in the second direction X. The second direction X is a direction orthogonal to the first direction Z. The fixing member 140 fixes the cold plate P1 and the cold plate P2. The fixing member 140 is formed by, for example, bending a plate made of a sheet metal. At least a portion of the fixing member 140 extends in the first direction Z. The cold plate P1 is fixed to an end of the fixing member 140 on the one side Z1 in the first direction Z by using a screw 145. The cold plate P2 is fixed to an end of the fixing member 140 on the other side Z2 in the first direction Z by using a screw 145. The cold plate P1 is fixed to the fixing member 140 while pressing the heat generating component 500 toward the other side 22 in the first direction Z. The cold plate P2 is fixed to the fixing member 140 while pressing the heat generating component 500 toward the one side Z1 in the first direction Z. Therefore, the heat generating component 500 can be prevented from moving in the direction intersecting the first direction Z.

In the present example embodiment, the support member 130 is fixed to the fixing member 140 using a screw 146. The support member 130 may not be fixed to the fixing member 140.

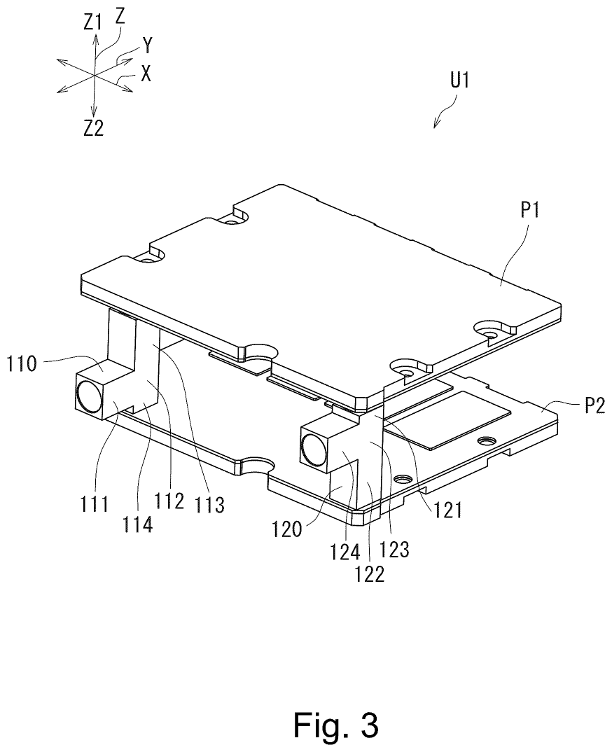

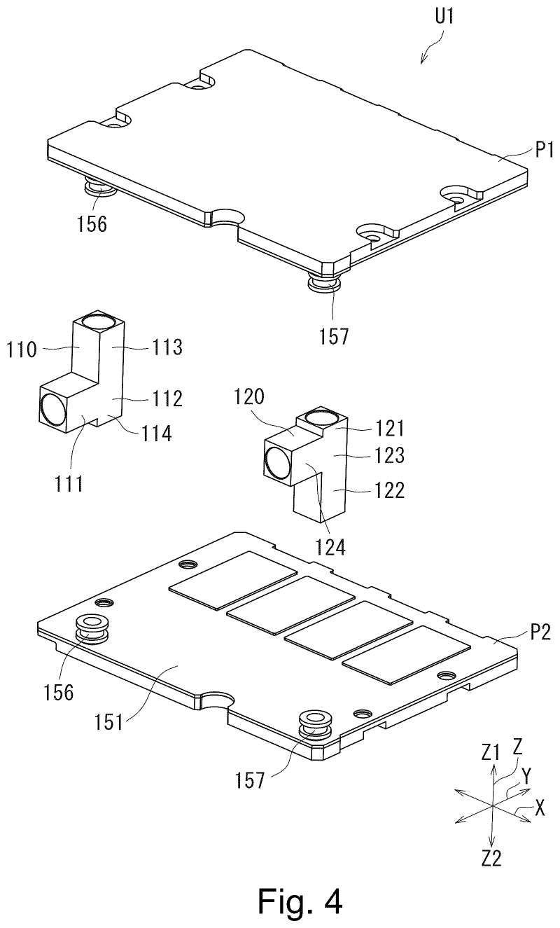

Next, structures of the cold plate P1, the cold plate P2, the inflow pipe 110, and the outflow pipe 120 of the cooling assembly U1 will be described in detail with reference to FIGS. 3 and 4. FIG. 3 is a perspective view illustrating the structures of the cold plate P1, the cold plate P2, the inflow pipe 110, and the outflow pipe 120 of the cooling assembly U1. FIG. 4 is an exploded perspective view illustrating the structures of the cold plate P1, the cold plate P2, the inflow pipe 110, and the outflow pipe 120 of the cooling assembly U1.

As illustrated in FIGS. 3 and 4, the cold plate P1 and the cold plate P2 each have a substantially flat plate shape. The cold plate P1 and the cold plate P2 are disposed parallel to each other. The cold plate P1 and the cold plate P2 are separated from each other by a predetermined distance in the first direction Z.

At least a portion of the cold plate P1 and at least a portion of the cold plate P2 overlap in the first direction Z. In the present example embodiment, substantially the entire cold plate P1 and substantially the entire cold plate P2 overlap each other in the first direction Z.

At least a portion of the inflow pipe 110 and at least a portion of the outflow pipe 120 are located between the cold plate P1 and the cold plate P2 in the first direction Z. Therefore, it is possible to suppress an increase in size of the cooling assembly U1.

The inflow pipe 110 includes a common inflow portion 111, a branch portion 112, a first connection portion 113, and a second connection portion 114. The common inflow portion 111 is connected to the manifold M1 (see FIG. 2). The branch portion 112 branches the refrigerant passing through the common inflow portion 111. The first connection portion 113 connects the branch portion 112 and the cold plate P1. The second connection portion 114 connects the branch portion 112 and the cold plate P2. Accordingly, the refrigerant from the manifold M1 passes through the common inflow portion 111, is branched by the branch portion 112, and then flows into the cold plate P1 or the cold plate P2 via the first connection portion 113 or the second connection portion 114. As described above, the inflow pipe 110 includes the common inflow portion 111, the branch portion 112, the first connection portion 113, and the second connection portion 114, so that the refrigerant can flow into the two cold plates (cold plate P1 and P2) by the one inflow pipe 110. Therefore, it is possible to suppress an increase in the number of inflow pipes 110.

The outflow pipe 120 includes a third connection portion 121, a fourth connection portion 122, a merging portion 123, and a common outflow portion 124. The third connection portion 121 is connected to the cold plate P1. In other words, the third connection portion 121 connects the cold plate P1 and the merging portion 123. The fourth connection portion 122 is connected to the cold plate P2. In other words, the fourth connection portion 122 connects the cold plate P2 and the merging portion 123. The merging portion 123 merges the refrigerant passing through the third connection portion 121 and the refrigerant passing through the fourth connection portion 122. The refrigerant having passed through the merging portion 123 passes through the common outflow portion 124. The common outflow portion 124 is connected to the manifold M2 (see FIG. 2). Accordingly, the refrigerant from the cold plate P1 and the cold plate P2 passes through the third connection portion 121 and the fourth connection portion 122, merges at the merging portion 123, and then flows out to the manifold M2 via the common outflow portion 124. As described above, the outflow pipe 120 includes the third connection portion 121, the fourth connection portion 122, the merging portion 123, and the common outflow portion 124, so that the refrigerant can flow out of the two cold plates (cold plates P1 and P2) by the one out flow pipe 120. Therefore, it is possible to suppress an increase in the number of the outflow pipes 120.

The first connection portion 113 of the inflow pipe 110 is connected to an inflow port 156 provided on a surface (contact surface 151 to be described later) of the cold plate P1 on the cold plate P2 side. The second connection portion 114 of the inflow pipe 110 is connected to an outflow port 157 provided on a surface (contact surface 151 to be described later) of the cold plate P2 on the cold plate P1 side.

Further, in the present example embodiment, the inflow pipe 110 has a substantially T shape. Specifically, the first connection portion 113, the branch portion 112, and the second connection portion 114 are arranged in a straight line along the first direction Z. The first connection portion 113, the branch portion 112, and the second connection portion 114 are located between the cold plate P1 and the cold plate P2 in the first direction Z. The common inflow portion 111 extends in the third direction Y orthogonal to the first direction Z and the second direction X.

In the present example embodiment, the outflow pipe 120 has a substantially T shape. Specifically, the third connection portion 121, the merging portion 123, and the fourth connection portion 122 are arranged in a straight line along the first direction Z. The third connection portion 121, the merging portion 123, and the fourth connection portion 122 are located between the cold plate P1 and the cold plate P2 in the first direction Z. The common outflow portion 124 extends in the third direction Y. The common inflow portion 111 and the common outflow portion 124 are disposed in parallel to each other, for example.

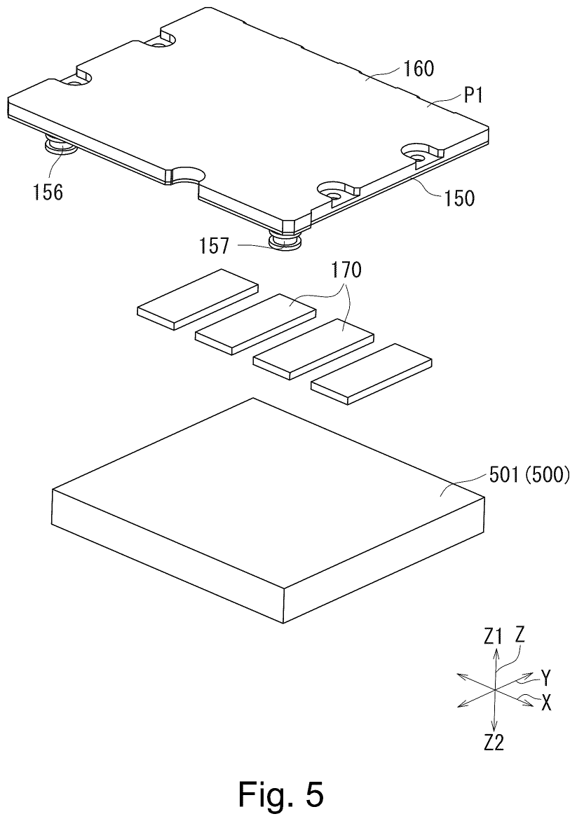

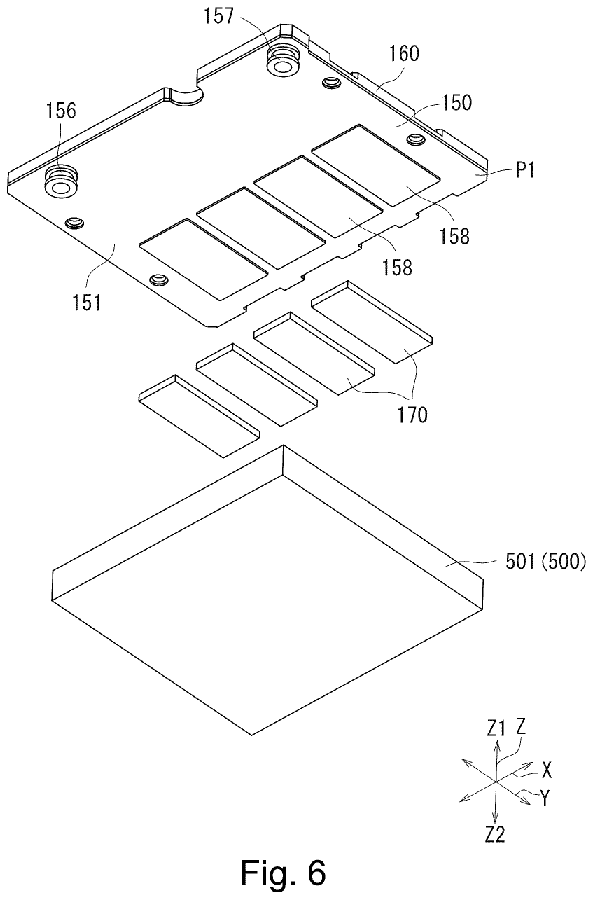

Next, a structure around the cold plate P1 will be described with reference to FIGS. 5 and 6. FIGS. 5 and 6 are exploded perspective views illustrating the cold plate P1, the heat conductor 170, and the first heat generating component 501 of the cooling assembly U1. Since the structure around the cold plate P1 and the structure around the cold plate P2 are substantially the same in the first direction Z, the description of the structure around the cold plate P2 will be omitted.

The cold plate P1 has a contact surface 151 that comes into contact with the heat generating component 500. The contact surface 151 may be in direct contact with the heat generating component 500 or may be in indirect contact therewith. In the present example embodiment, the cooling assembly U1 further includes the heat conductor 170. The heat conductor 170 is located between the contact surface 151 and the heat generating component 500. The contact surface 151 is in indirect contact with the heat generating component 500 via the heat conductor 170.

In the present example embodiment, as described above, the heat conductor 170 is located between the cold plate P1 and the heat generating component 500. Therefore, for example, even when the surface of the cold plate P1 or the heat generating component 500 has small irregularities, the heat conductor 170 is buried in the irregularities, and the air layer is prevented from being interposed between the cold plate P1 and the heat generating component 500. Accordingly, the heat of the heat generating component 500 is efficiently transferred to the cold plate P1, so that the heat dissipation of the heat generating component 500 improves.

The heat conductor 170 only needs to be made of a material capable of efficiently performing heat conduction, and for example, a heat conduction sheet, grease, or the like can be used. The heat conductive sheet may be, for example, an elastic sheet such as a rubber sheet. In the present example embodiment, the heat conductor 170 is a heat conduction sheet having a predetermined thickness. Note that inclusion of particles having a high thermal conductivity in the heat conductor 170 makes it possible to further improve the thermal conductivity of the heat conductor 170.

One or more heat conductors 170 are provided. In the present example embodiment, a plurality of (here, four) heat conductors 170 are provided. Note that the heat conductor 170 may be, for example, one heat conductor having a size covering the plurality of heat conductors 170 illustrated in FIGS. 5 and 6. The heat conductor 170 is disposed in a region of the heat generating component 500 particularly requiring cooling. For example, the heat conductor 170 is disposed in a region of the heat generating component 500 that is likely to have a high temperature.

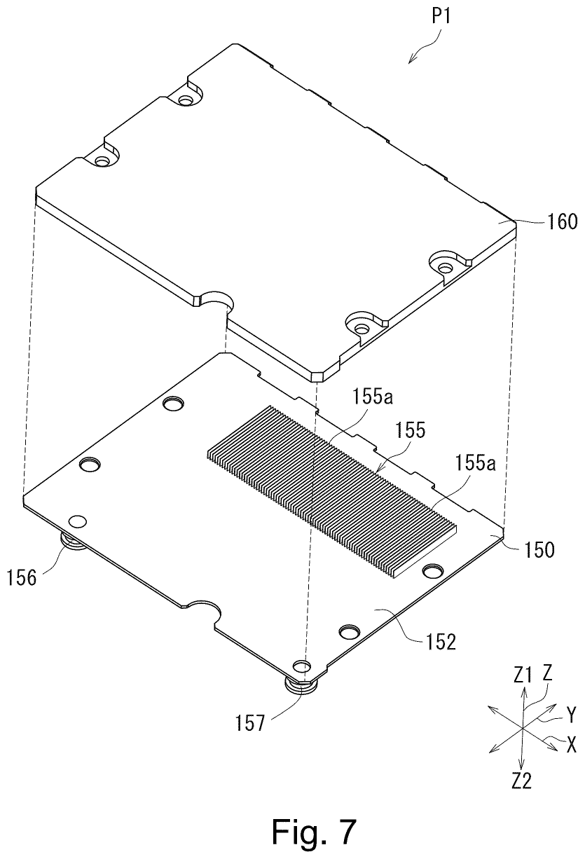

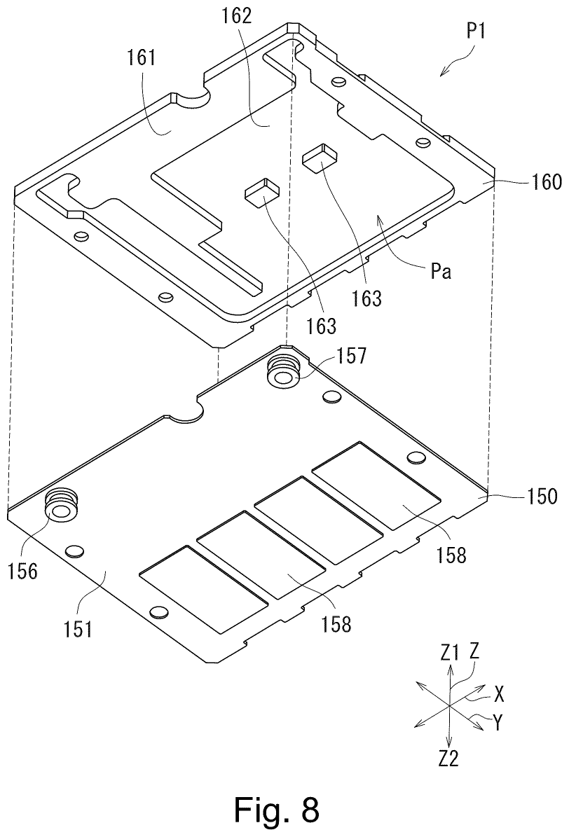

Next, the structure of the cold plate P1 will be described in detail with reference to FIGS. 7 to 12. FIGS. 7 and 8 are exploded perspective views illustrating the structure of the cold plate P1 of the cooling assembly U1. Since the structure around the cold plate P1 and the structure around the cold plate P2 are substantially the same in the first direction Z, the description of the structure around the cold plate P2 will be omitted.

As illustrated in FIGS. 7 and 8, the cold plate P1 is made of a metal having high thermal conductivity such as copper or aluminum. The cold plate P1 is a rectangular plate component extending in the second direction X and the third direction Y. Note that the shape of the cold plate P1 may be other than a rectangular shape.

The cold plate P1 includes a first member 150 and a second member 160. The first member 150 is provided on the heat generating component 500 (see FIG. 5) side of the cold plate P1, and the second member 160 is provided on the opposite side of the cold plate P1 from the heat generating component 500.

The cold plate P1 includes an internal flow path Pa and a fin assembly 155. The refrigerant passes through the internal flow path Pa. The internal flow path Pa is disposed so as to overlap the contact surface 151 in the first direction Z. The internal flow path Pa includes the first member 150 and the second member 160. In other words, the first member 150 and the second member 160 constitute the internal flow path Pa. Specifically, the first member 150 has an inner surface 152 provided on the second member 160 side. The inner surface 152 is a flat surface. The second member 160 has an inner surface 161 provided on the first member 150 side and a recess 162 provided on the inner surface 161. The first member 150 and the second member 160 are fixed by welding, brazing, or the like in a state where the inner surface 152 and the inner surface 161 are in close contact with each other. The internal flow path Pa is configured of the inner surface 152 of the first member 150 and the recess 162 of the second member 160.

The fin assembly 155 is disposed in the internal flow path Pa. The fin assembly 155 includes a plurality of fins 155a. Since the fin assembly 155 has a large contact area with the refrigerant, heat is efficiently transmitted to the refrigerant. The fin assembly 155 is provided on the first member 150, for example. In the present example embodiment, the fins 155a and the first member 150 are integrated parts. The fins 155a are formed by, for example, skiving in which the surface of first member 150 is thinly shaved and raised. The method for forming the fins 155a is not limited to skiving.

The first member 150 has the inflow port 156 and the outflow port 157. The inflow port 156 and the outflow port 157 are provided on the contact surface 151 of the first member 150. The inflow port 156 is connected to the inflow pipe 110 (see FIG. 4). The inflow port 156 is connected to the internal flow path Pa. The refrigerant having passed through the inflow pipe 110 flows into the internal flow path Pa via the inflow port 156. Meanwhile, the outflow port 157 is connected to the outflow pipe 120 (see FIG. 4). The outflow port 157 is connected to the internal flow path Pa. The refrigerant having passed through the internal flow path Pa flows out to the outflow pipe 120 via the inflow port 156.

In addition, the first member 150 has, for example, the same number of protrusions 158 (see FIG. 8) as the heat conductor 170. The protrusion 158 is provided on the contact surface 151. The size of the protrusion 158 is not particularly limited, but is, for example, the same as that of the heat conductor 170 or slightly larger than that of the heat conductor 170.

Each protrusion 158 overlaps at least a portion of the heat conductor 170 in the first direction Z. Accordingly, alignment between the cold plate P1 and the heat conductor 170 is facilitated. Each region R2 described later overlaps at least a portion of the protrusion 158 and at least a portion of the heat conductor 170.

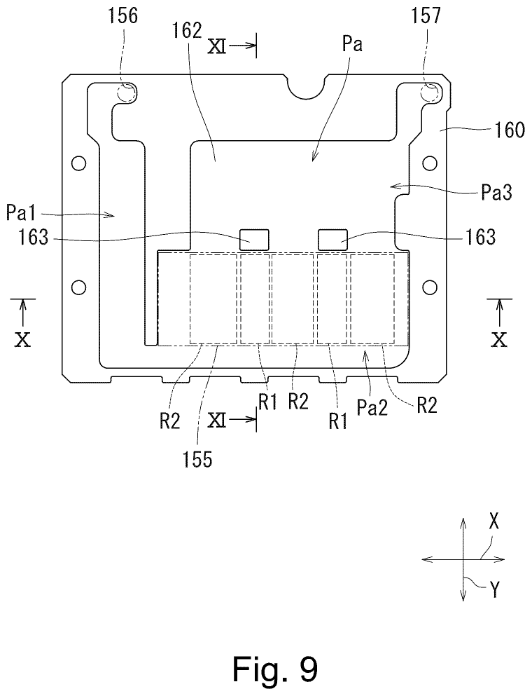

FIG. 9 is a diagram illustrating the structure of the second member 160 of the cold plate P1 of the cooling assembly U1 from the other side Z2 in the first direction Z. As illustrated in FIG. 9, the internal flow path Pa includes an upstream portion Pa1, a fin accommodating portion Pa2, and a downstream portion Pa3.

The upstream portion Pa1 is disposed upstream of the fin accommodating portion Pa2 in the refrigerant flowing direction. The upstream portion Pa1 connects the inflow port 156 and the fin accommodating portion Pa2. The fin accommodating portion Pa2 accommodates the fin assembly 155. The downstream portion Pa3 is disposed downstream of the fin accommodating portion Pa2 in the refrigerant flowing direction. The downstream portion Pa3 connects the fin accommodating portion Pa2 and the outflow port 157. The refrigerant flowing from the inflow port 156 passes through the upstream portion Pa1, the fin accommodating portion Pa2, and the downstream portion Pa3 in this order, and flows out from the outflow port 157.

As illustrated in FIG. 7, the plurality of fins 155a are arranged in the second direction X orthogonal to the first direction Z. In other words, the plurality of fins 155a are disposed in the second direction X. The plurality of fins 155a are separated from each other in the second direction X. Each fin 155a extends in the third direction Y. Therefore, in the fin accommodating portion Pa2 (see FIG. 9), the refrigerant flows in the third direction Y.

As illustrated in FIGS. 8 and 9, the cold plate P1 includes a partition 163. In the present example embodiment, the partition 163 is provided on the second member 160. The partition 163 may be provided on the first member 150. The cold plate P1 includes one or more (two in this example embodiment) partitions 163.

As described above, the fin assembly 155 is provided on the first member 150, and the partition 163 is provided on the second member 160. Therefore, the fin assembly 155 and the partition 163 can be formed on separate members. Therefore, when the fins 155a of the fin assembly 155 are skived, the cutting blade can be prevented from coming into contact with the partition 163.

The partition 163 is disposed in the internal flow path Pa, and partitions the internal flow path Pa into a plurality of flow paths. Specifically, the partition 163 is disposed adjacent to the fin assembly 155 in the third direction Y. In the present example embodiment, the partition 163 is provided on the downstream side in the refrigerant flowing direction with respect to the fin assembly 155, but may be provided on the upstream side in the refrigerant flowing direction with respect to the fin assembly 155.

In a region R1 of the fin assembly 155 where the fins 155a adjacent to the partition 163 are disposed, the flow velocity of the refrigerant is reduced. That is, the amount of refrigerant flowing through the region R1 decreases. On the other hand, in a region R2 of the fin assembly 155 where the fins 155a not adjacent to the partition 163 are disposed, the flow velocity of the refrigerant is faster than that in the region R1. That is, the amount of refrigerant flowing through the region R2 increases. Therefore, in the present example embodiment, the internal flow path Pa is partitioned into a plurality of (here, three) flow paths (region R2) by the partition 163. The plurality of regions R2 are examples of “a plurality of flow paths” of the present disclosure.

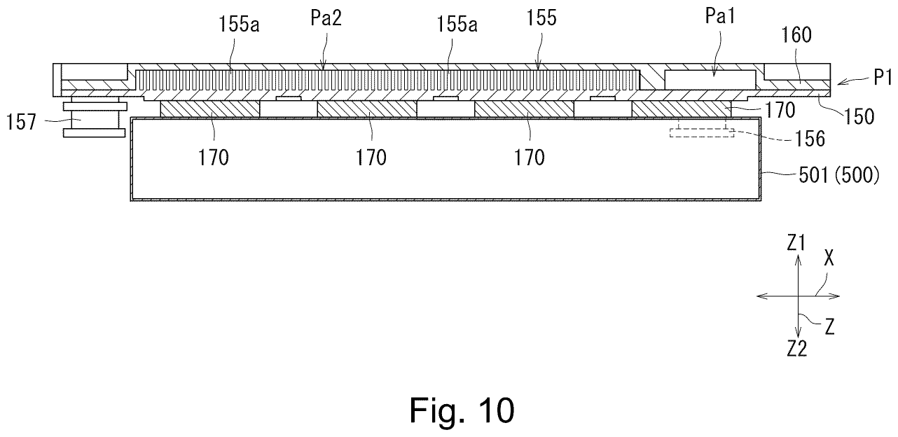

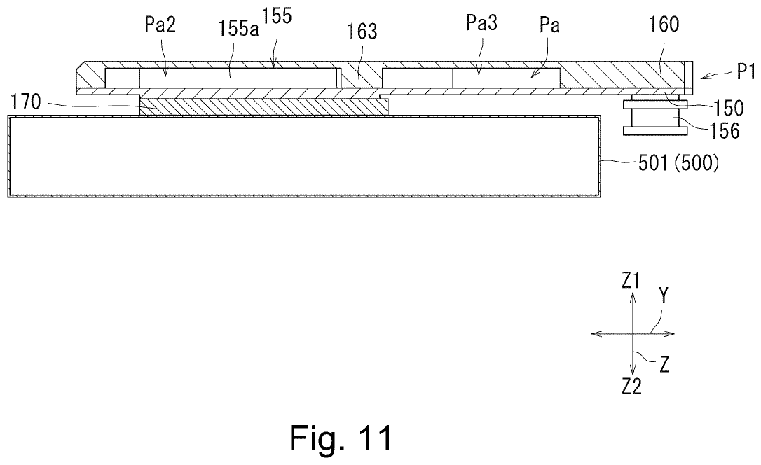

FIG. 10 is a cross-sectional view of the cold plate P1, the heat conductor 170, and the first heat generating component 501 of the cooling assembly U1 taken along line X-X in FIG. 9. FIG. 11 is a cross-sectional view of the cold plate P1, the heat conductor 170, and the first heat generating component 501 of the cooling assembly U1 taken along line XI-XI in FIG. 9.

As illustrated in FIGS. 10 and 11, the fin assembly 155 and the heat conductor 170 are disposed such that the heat conductor 170 and the fin assembly 155 overlap each other in the first direction Z. Therefore, since the heat of the heat generating component 500 can be efficiently transferred to the fin assembly 155 via the heat conductor 170, the cooling effect can be improved.

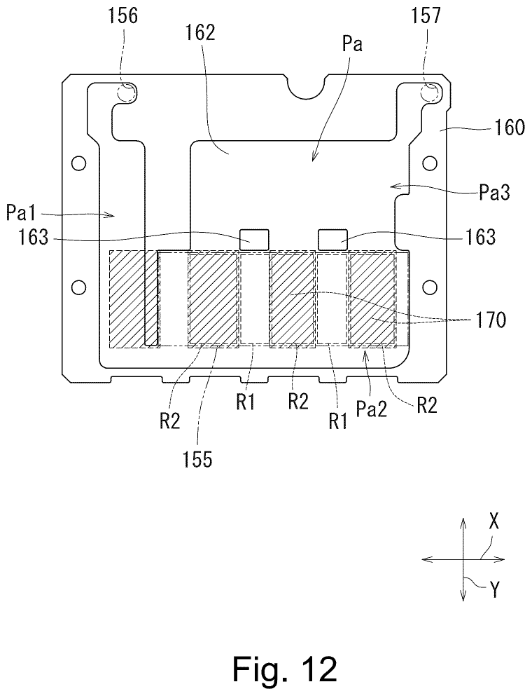

FIG. 12 is a diagram illustrating a positional relationship between the heat conductor 170 of the cooling assembly U1 and the internal flow path Pa. In FIG. 12, the heat conductor 170 is hatched for easy understanding. As illustrated in FIG. 12, when viewed from the first direction Z, the heat conductor 170 is disposed in the region R2 where the flow rate of the refrigerant is relatively high in the internal flow path Pa. In other words, the region R2 and the heat conductor 170 overlap each other when viewed from the first direction Z. Therefore, a large amount of refrigerant can pass through the portion (region R2) having high heat dissipation performance. Therefore, the heat generating component 500 can be cooled more efficiently.

As described above, the cold plate P1 includes the partition 163 that partitions the internal flow path Pa into a plurality of flow paths. Therefore, the fin assembly 155 can be easily set to a portion (region R2) through which the refrigerant easily passes and a portion (region R1) through which the refrigerant hardly passes.

### First Modification

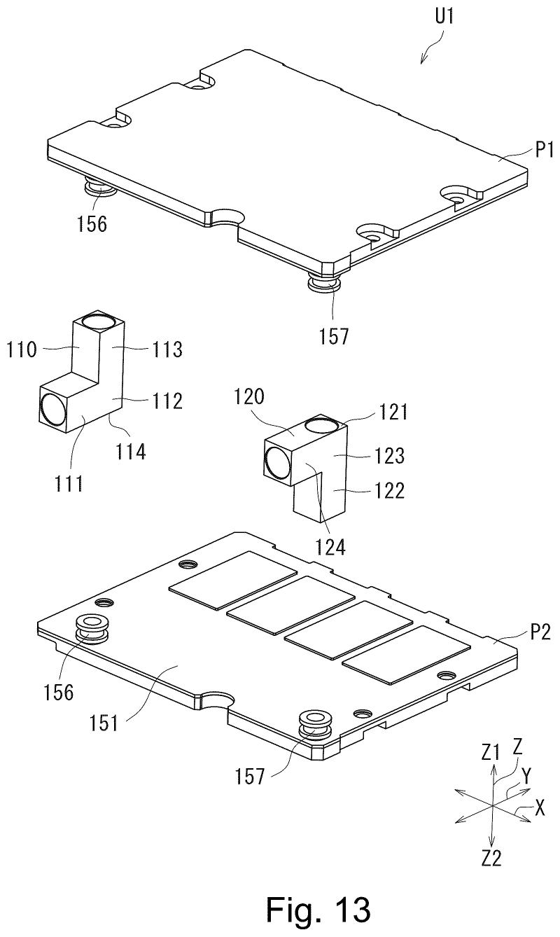

A first modification of the first example embodiment of the present disclosure will be described with reference to FIG. 13. FIG. 13 is a perspective view illustrating a structure of a cooling assembly U1 according to the first modification of the first example embodiment.

As illustrated in FIG. 13, in the cooling assembly U1 of the first modification, an inflow pipe 110 and an outflow pipe 120 have different shapes from the inflow pipe 110 and the outflow pipe 120 of the example embodiment illustrated in FIGS. 1 to 12. The inflow pipe 110 and the outflow pipe 120 each have a substantially L shape. That is, the surface of the second connection portion 114 may be substantially flush with the surface of the common inflow portion 111. The surface of the third connection portion 121 may be substantially flush with the surface of the common outflow portion 124. Note that the surface of the first connection portion 113 may be substantially flush with the surface of the common inflow portion 111. The surface of the fourth connection portion 122 may be substantially flush with the surface of the common outflow portion 124.

### Second Modification

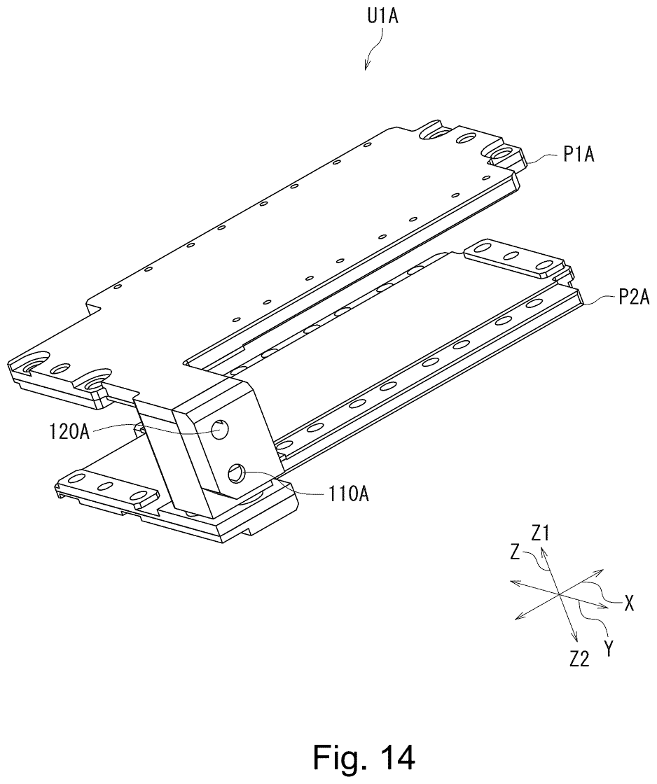

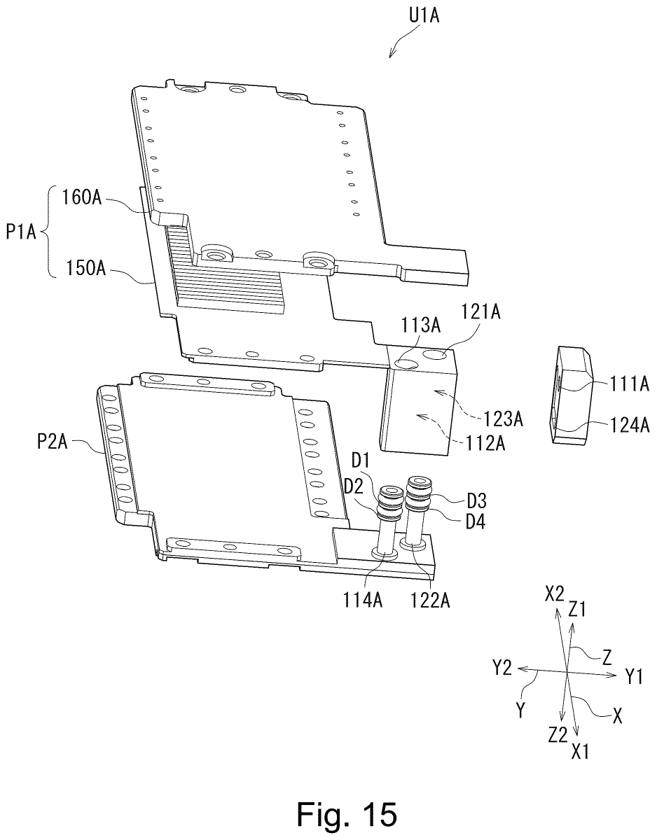

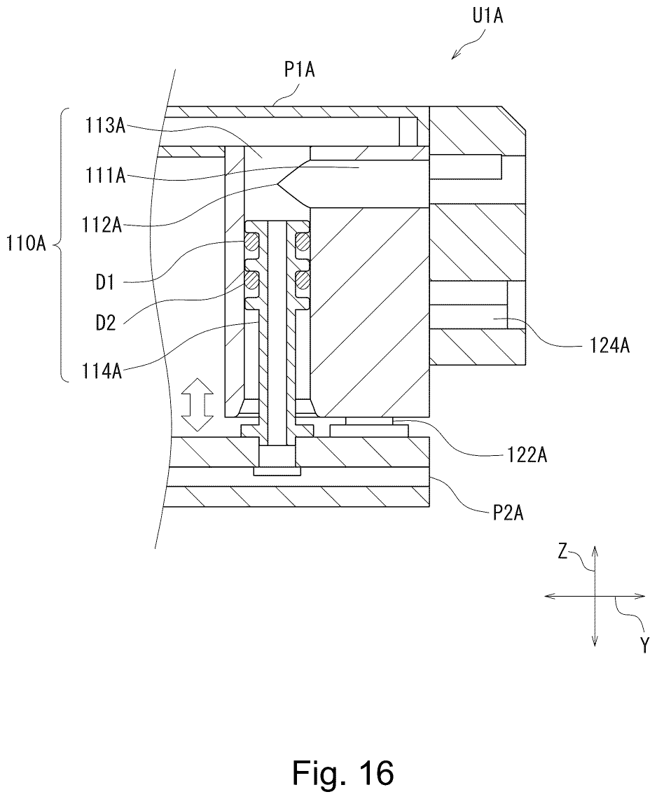

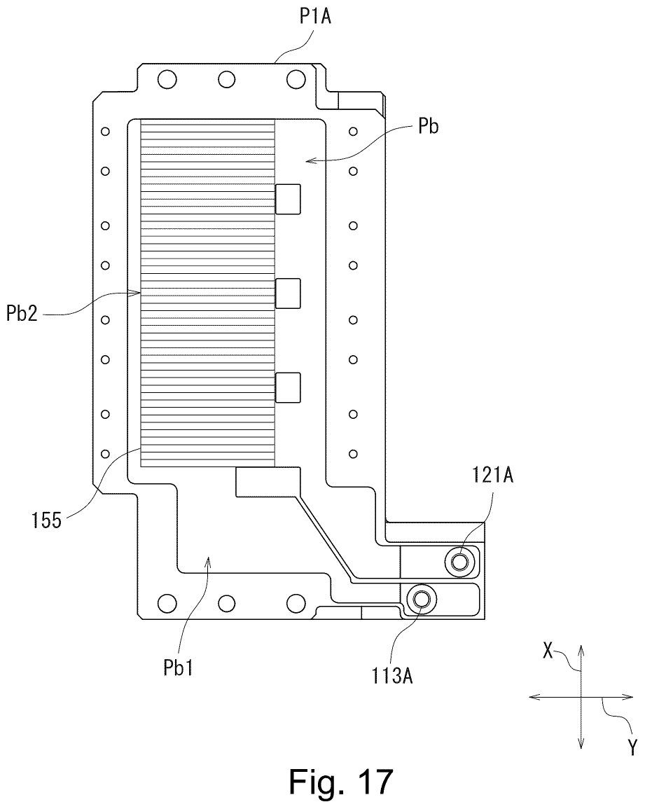

A second modification of the first example embodiment of the present disclosure will be described with reference to FIGS. 14 to 17. FIG. 14 is a perspective view illustrating a structure of a cooling assembly U1A according to the second modification of the first example embodiment. FIG. 15 is an exploded perspective view illustrating the structure of the cooling assembly U1A according to the second modification of the first example embodiment. FIG. 16 is a cross-sectional view of the cooling assembly U1A according to the second modification of the first example embodiment. FIG. 17 is a cross-sectional view of the cooling assembly U1A according to the second modification of the first example embodiment.

In the present example embodiment, the cooling assembly U1A of the second modification is used in the cooling system 100 instead of the cooling assembly U1 or the cooling assembly U1 of the first modification.

As illustrated in FIG. 14, the cooling assembly U1A includes a cold plate P1A, a cold plate P2A, an inflow pipe 110A, and an outflow pipe 120A. The cold plate P1A is the same as the cold plate P1 except that the shape of the cold plate P1A is different from that of the cold plate P1. The cold plate P2A is the same as the cold plate P2 except that the shape of the cold plate P2A is different from that of the cold plate P2.

Next, the structures of the cold plate P1A, the inflow pipe 110A, and the outflow pipe 120A will be described in detail with reference to FIGS. 15 and 16. As illustrated in FIG. 15, the cold plate P1A includes a first member 150A and a second member 160A. The first member 150A is the same as the first member 150 except that the shape of the first member 150A is different from that of the first member 150. The second member 160A is the same as the second member 160 except that the shape of the second member 160A is different from that of the second member 160.

The Inflow pipe 110A and the outflow pipe 120A are different in shape from the inflow pipe 110 and the outflow pipe 120, respectively. Specifically, the inflow pipe 110A includes a common inflow portion 111A, a branch portion 112A, a first connection portion 113A, and a second connection portion 114A. The outflow pipe 120A includes a third connection portion 121A, a fourth connection portion 122A, a merging portion 123A, and common outflow portion 124A.

As illustrated in FIGS. 15 and 16, the first connection portion 113A is provided in the cold plate P1A instead of the inflow port 156 in the cold plate P1. The first connection portion 113A is a pipe that penetrates the second member 160A of the cold plate P1A and extends toward the cold plate P2A along the first direction Z. The position of the first connection portion 113A in the cold plate P1A is different from the position of the inflow port 156 in the cold plate P1.

On the other hand, the second connection portion 114A is provided on the cold plate P2A. Specifically, the second connection portion 114A is a pipe extending from the cold plate P2A toward the cold plate P1A along the first direction Z.

As illustrated in FIG. 16, the inflow port of the second connection portion 114A is disposed inside the first connection portion 113A. Specifically, the second connection portion 114A is inserted into the first connection portion 113A from the end of the first connection portion 113A on the other side 22 in the first direction Z. That is, at least a portion of the second connection portion 114A is located inside the first connection portion 113A.

The first connection portion 113A is provided with the branch portion 112A. In a state where the second connection portion 114A is inserted into the first connection portion 113A, the first connection portion 113A connects the branch portion 112A and the cold plate P1A, and the second connection portion 114A connects the branch portion 112A and the cold plate P2A.

Further, the common inflow portion 111A is connected to the branch portion 112A. As a result, the refrigerant having passed through the common inflow portion 111A is divided to flow into the first connection portion 113A and the second connection portion 114A by the branch portion 112A, and flows into the cold plate P1A or the cold plate P2A via the first connection portion 113A or the second connection portion 114A.

The third connection portion 121A is provided to the cold plate P1A instead of the outflow port 157 of the cold plate P1. The third connection portion 121A is a pipe that penetrates the second member 160A of the cold plate P1A and extends toward the cold plate P2A along the first direction Z. Note that the position of the third connection portion 121A in the cold plate P1A is different from the position of the outflow port 157 in the cold plate P1.

On the other hand, the fourth connection portion 122A is provided to the cold plate P2A. Specifically, the fourth connection portion 122A is a pipe extending from the cold plate P2A toward the cold plate P1A along the first direction Z.

Similarly to the first connection portion 113A and the second connection portion 114A, the outflow port of the fourth connection portion 122A is disposed inside the third connection portion 121A. Specifically, the fourth connection portion 122A is inserted into the third connection portion 121A from the end of the third connection portion 121A on the other side Z2 in the first direction Z. That is, at least a portion of the fourth connection portion 122A is located inside the third connection portion 121A.

The third connection portion 121A is provided with the merging portion 123A. In a state where the fourth connection portion 122A is inserted into the third connection portion 121A, the third connection portion 121A connects the merging portion 123A and the cold plate P1A, and the fourth connection portion 122A connects the merging portion 123A and the cold plate P2A.

Further, the common outflow portion 124A is connected to the merging portion 123A. The merging portion 123 merges the refrigerant passing through the third connection portion 121A and the refrigerant passing through the fourth connection portion 122A. The refrigerant having passed through the merging portion 123A passes through the common outflow portion 124A.

As described above, the second connection portion 114A and the fourth connection portion 122A are configured to be insertable into the first connection portion 113A and the third connection portion 121A, respectively, so that the second connection portion 114A and the fourth connection portion 122A are movable along the first connection portion 113A and the third connection portion 121A, respectively. In other words, the inflow pipe 110A and the outflow pipe 120A extend and contract in the first direction Z. That is, even in a state where the cold plate P1A and the cold plate P2A are connected to each other, the cold plate P1A or the cold plate P2A can be easily moved along the first direction Z, and the distance between the cold plate P1A and the cold plate P2A can be easily increased or decreased.

As a result, the cold plate P2A is movable with respect to the cold plate P1A. This facilitates the operation of disposing the heat generating component between the cold plate P1A and the cold plate P2A. Since the distance between the cold plate P1A and the cold plate P2A can be easily changed, the contact accuracy between the cold plate P1A and the cold plate P2A with respect to the heat generating component located between the cold plate P1A and the cold plate P2A can be improved.

As illustrated in FIGS. 15 and 16, elastic portions D1 and D2 are provided on the second connection portion 114A. More specifically, the elastic portions D1 and D2 are located between the inflow port of the second connection portion 114A and the inside of the first connection portion 113A. The elastic portions D1 and D2 are, for example, O-rings, packings, gaskets, and the like. In the example illustrated in FIGS. 15 and 16, the elastic portions D1 and D2 are O-rings. The outer diameter of the O-ring is, for example, substantially the same as the width of the inside of the first connection portion 113A. The inner diameter of the O-ring is, for example, substantially the same as the outer diameter of the second connection portion 114A. In the example illustrated in FIGS. 15 and 16, the elastic portions D1 and D2 are arranged with a predetermined distance along the first direction Z, but the number and positions of the elastic portions arranged on the second connection portion 114A are not limited to the example illustrated in FIGS. 15 and 16.

On the other hand, as illustrated in FIG. 15, elastic portions D3 and D4 are provided on the fourth connection portion 122A. More specifically, the elastic portions D3 and D4 are located between the outflow port of the fourth connection portion 122A and the inside of the third connection portion 121A. Since the elastic portions D3 and D4 are the same as the elastic portions D1 and D2, description and illustration in FIG. 16 are omitted.

In this manner, by disposing the elastic portions D1, D2, D3, and D4 between the first connection portion 113A and the second connection portion 114A and between the third connection portion 121A and the fourth connection portion 122A, it is possible to more reliably block between the first connection portion 113A and the second connection portion 114A and between the third connection portion 121A and the fourth connection portion 122A and to suppress leakage of the refrigerant to the outside of the cold plate P1A and the cold plate P2A.

Note that the relationship between the first connection portion 113A and the second connection portion 114A and the relationship between the third connection portion 121A and the fourth connection portion 122A may be reversed. That is, the inflow port of the first connection portion 113A may be disposed inside the second connection portion 114A, and the outflow port of the third connection portion 121A may be disposed inside the fourth connection portion 122A. In that case, the elastic portions D1 and D2 are located between the inflow port of the first connection portion 113A and the inside of the second connection portion 114A. The elastic portions D3 and D4 are located between the outflow port of the third connection portion 121A and the inside of the fourth connection portion 122A.

In the present example embodiment, the cold plate P1A, the first connection portion 113A, and the third connection portion 121A are defined by a single monolithic portion. The cold plate P2A, the second connection portion 114A, and the fourth connection portion 122A are defined by a single monolithic portion. When the cold plate P1A, the first connection portion 113A, and the third connection portion 121A, and the cold plate P2A, the second connection portion 114A, and the fourth connection portion 122A are made of the same material, ionization caused by the refrigerant and the cold plate P1A, the first connection portion 113A, and the third connection portion 121A, the cold plate P2A, the second connection portion 114A, and the fourth connection portion 122A can be suppressed. With the above configuration, the cold plate P1A or the cold plate P2A can be moved more easily by reducing the influence of friction between the first connection portion 113A and the second connection portion 114A and between the third connection portion 121A and the fourth connection portion 122A.

In the present example embodiment, the first connection portion 113A and the second connection portion 114A are provided on the one side X1 in the second direction X and the one side Y1 in the third direction Y of the cold plate P1A. On the other hand, the third connection portion 121A and the fourth connection portion 122A are provided on the one side X1 in the second direction X and the one side Y1 in the third direction Y of the cold plate P1A. That is, the third connection portion 121A and the fourth connection portion 122A, and the third connection portion 121A and the fourth connection portion 122A are arranged adjacent to each other. With such a configuration, in a state where the cold plate P1A and the cold plate P2A are connected to each other, it is easy to slide and dispose the heat generating component between the cold plate P1A and the cold plate P2A from the other side X2 in the second direction X or the other side Y2 in the third direction Y.

Note that the arrangement of the first connection portion 113A and the second connection portion 114A and the arrangement of the third connection portion 121A and the fourth connection portion 122A are not limited to the above arrangement. For example, the first connection portion 113A and the second connection portion 114A, and the third connection portion 121A and the fourth connection portion 122A may be disposed at diagonal positions of the cold plate P1A.

Next, a flow path of the refrigerant in the cold plate P1A will be described with reference to FIG. 17. FIG. 17 is a cross-sectional view illustrating the internal structure of the cold plate P1A. FIG. 17 illustrates a cross section of the cold plate P1A on a plane along the second direction X and the third direction Y.

As illustrated in FIG. 17, a fin assembly 155 is provided on the cold plate P1A to form an internal flow path Pb. The internal flow path Pb is connected to the first connection portion 113A and the third connection portion 121A. The refrigerant having passed through the first connection portion 113A flows into the internal flow path Pb. The refrigerant having passed through the internal flow path Pb flows out to the third connection portion 121A.

Specifically, the internal flow path Pb includes an upstream portion Pb1, a fin accommodating portion Pb2, and a downstream portion Pb3. The upstream portion Pb1 is disposed upstream of the fin accommodating portion Pb2 in the refrigerant flowing direction. The upstream portion Pb1 connects the first connection portion 113A and the fin accommodating portion Pb2. The fin accommodating portion Pb2 accommodates the fin assembly 155. The downstream portion Pb3 is disposed downstream of the fin accommodating portion Pb2 in the refrigerant flowing direction. The downstream portion Pa3 connects the fin accommodating portion Pb2 and the third connection portion 121A. The refrigerant flowing from the first connection portion 113A passes through the upstream portion Pb1, the fin accommodating portion Pb2, and the downstream portion Pb3 in this order, and flows out from the third connection portion 121A.

### Second Example Embodiment

Next, a second example embodiment of the present disclosure will be described. The second example embodiment is different from the first example embodiment in that a cooling system 101 includes a cooling assembly U1B having a cold plate P3 different from the cold plates P1 and P2. Hereinafter, matters different from the first example embodiment will be described in the second example embodiment, and description of the same matters as those of the first example embodiment will be omitted.

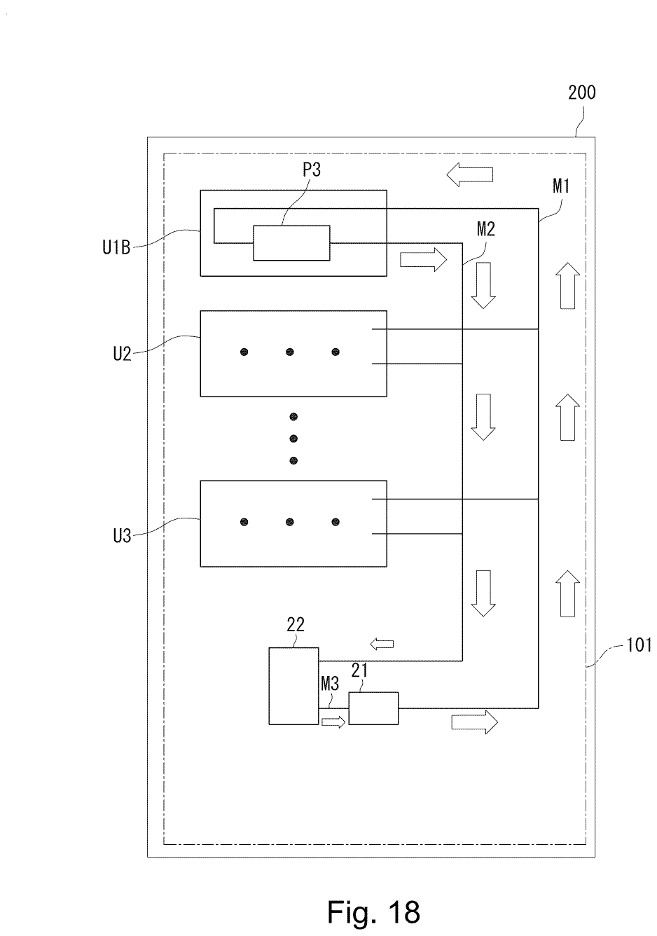

With reference to FIG. 18, the cooling system 101 having the cooling assembly U1B according to the second example embodiment of the present disclosure will be described. FIG. 18 is a schematic diagram of the cooling system 101 having the cooling assembly U1B according to the second example embodiment of the present disclosure.

The cooling system 101 includes the cooling assembly U1B instead of the cooling assembly U1 as compared with the cooling system 100 of the first example embodiment. The cooling assembly U1B includes the cold plate P3 instead of the cold plates P1 and P2. The cold plate P3 receives heat from the heat generating component and cools the heat generating component.

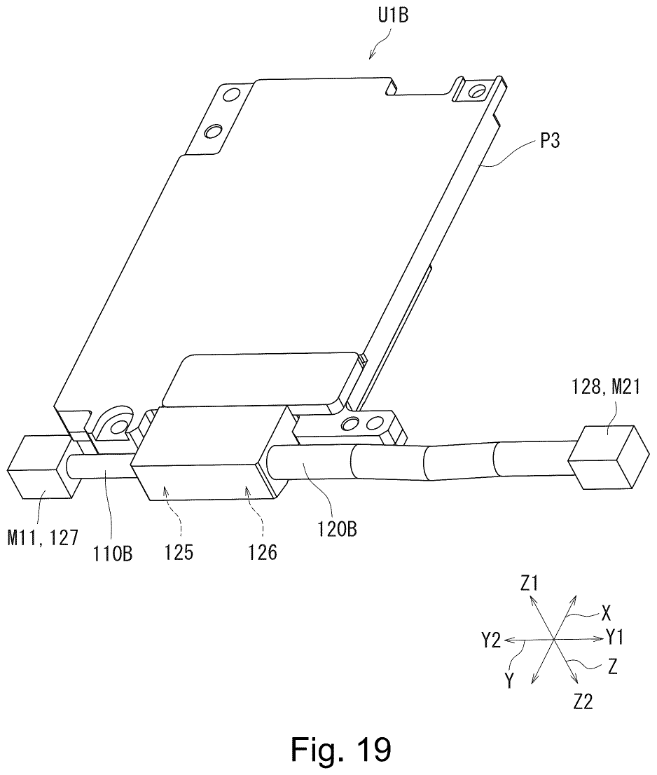

Next, the cooling assembly U1B including the cold plate P3 will be described in detail with reference to FIG. 19. FIG. 19 is a perspective view illustrating the cooling assembly U1B.

As illustrated in FIG. 19, the cooling assembly U1B includes the cold plate P3, an inflow pipe 110B, and an outflow pipe 120B. The cold plate P3 is an example of a “third cold plate” according to the present disclosure. The cold plate P3 is provided on the one side Z1 of a heat generating component (not illustrated) in the first direction Z. For example, a connection pipe M11 is connected to the inflow pipe 110B via the cold plate P3 and a seventh connection portion 127. More specifically, one end of the inflow pipe 110B is connected to the cold plate P3. The other end of the inflow pipe 110B is connected to the seventh connection portion 127. The inflow pipe 110B causes the refrigerant having passed through the connection pipe M11 and the seventh connection portion 127 to flow into the cold plate P3. The refrigerant having flown into the cold plate P3 flows out of the outflow pipe 120B through an internal flow path (not illustrated) formed in the cold plate P3. A connection pipe M21 is connected to the outflow pipe 120B via an eighth connection portion 128. More specifically, one end of the inflow pipe 110B is connected to the cold plate P3. The other end of the inflow pipe 110B is connected to the eighth connection portion 128. The outflow pipe 120B causes the refrigerant having passed through the cold plate P3 to flow out to the eighth connection portion 128 and the connection pipe M21. For example, the outflow pipe 120B is connected to the eighth connection portion 128 so as to be rotatable in the circumferential direction.

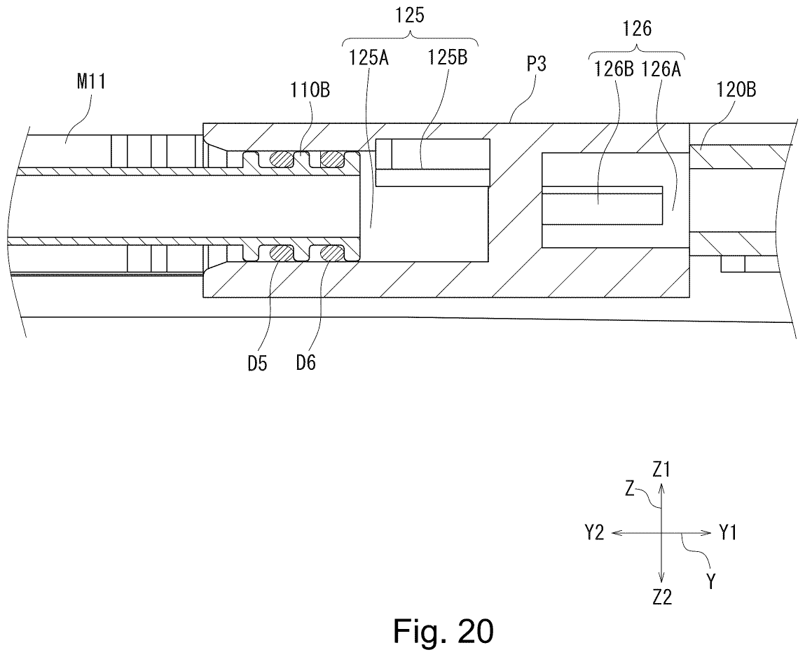

Next, the structures of the inflow pipe 110 and the outflow pipe 120 will be described in detail with reference to FIGS. 19 and 20. FIG. 20 is a cross-sectional view illustrating the structures of the inflow pipe 110 and the outflow pipe 120. FIG. 20 illustrates a cross section on a plane passing through the central axes of the inflow pipe 110 and the outflow pipe 120 and along the first direction Z and the third direction Y.

As illustrated in FIGS. 19 and 20, the cooling assembly U1B further includes a fifth connection portion 125 and a sixth connection portion 126. The fifth connection portion 125 and the sixth connection portion 126 are fixed to the cold plate P3. The fifth connection portion 125 is connected to the inflow pipe 110B. The sixth connection portion 126 is connected to the outflow pipe 120B.

For example, the inflow pipe 110B and the fifth connection portion 125 extend along the third direction Y. Specifically, the fifth connection portion 125 includes a tubular pipe portion 125A extending along the third direction Y, and an inflow port 125B connecting the pipe portion 125A and the cold plate P3 and allowing the refrigerant to flow into the cold plate P3. The inflow port 125B is disposed facing a direction intersecting the third direction Y in which the pipe portion 125A extends.

The inflow pipe 110B i disposed inside the fifth connection portion 125. Specifically, the inflow pipe 110B is inserted into the pipe portion 125A from the end on the other side Y2 in the third direction Y of the pipe portion 125A of the fifth connection portion 125. That is, at least a portion of the inflow pipe 110B is located inside the pipe portion 125A. Therefore, the pipe portion 125A of the fifth connection portion 125 is movable in the circumferential direction with respect to the inflow pipe 110B.

On the other hand, the sixth connection portion 126 includes a tubular pipe 126A extending along the third direction Y, and an outflow port 126B that connects the pipe portion 126A and the cold plate P3 and allows the refrigerant to flow out of the cold plate P3. The pipe portion 126A is connected to the outflow pipe 120B. The outflow port 126B is disposed facing a direction intersecting the third direction Y in which the pipe portion 126A extends.

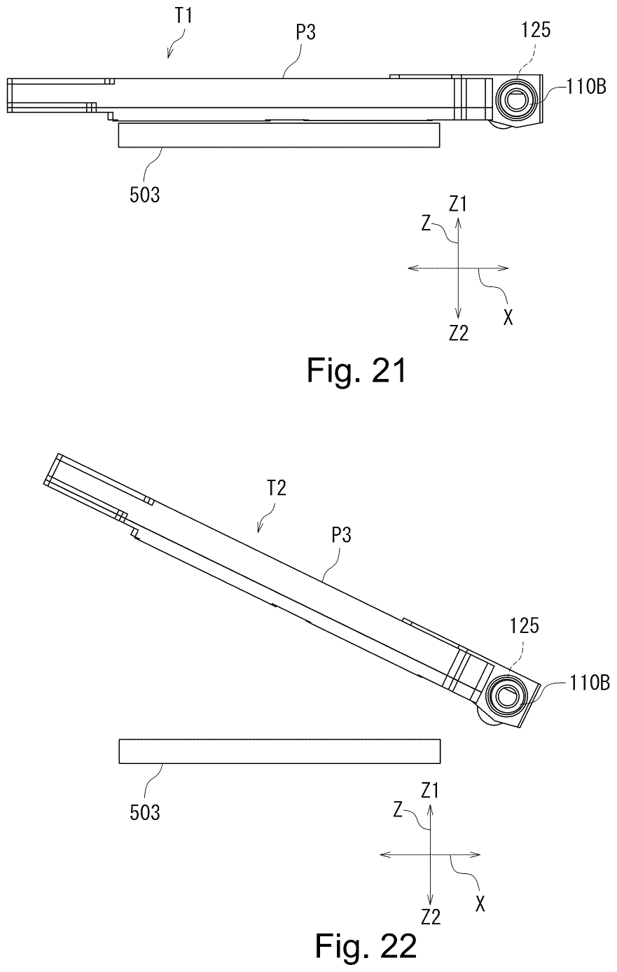

Since pipe portion 125A is movable in the circumferential direction with respect to the inflow pipe 110B and the outflow pipe 120B is rotatable in the circumferential direction with respect to the eighth connection portion 128, the cold plate P3 is rotatable about the inflow pipe 110B and the outflow pipe 120B as rotation axes (FIGS. 21 and 22). In other words, the cold plate P3 is rotatable with respect to the seventh connection portion 127 to which the inflow pipe 110B is connected and the eighth connection portion 128 to which the outflow pipe 120B is connected. That is, the cold plate P3 rotationally moves with respect to the heat generating component.

Next, rotational movement of the cold plate P3 will be described with reference to FIGS. 19 to 22. FIG. 21 is a diagram illustrating the cooling assembly U1B in which the cold plate P3 is located at a first position T1. FIG. 22 is a diagram illustrating the cooling assembly U1B in which the cold plate P3 is located at a second position T2.

In the cooling assembly U1B, the heat generating component 503 is provided on the other side Z2 of the cold plate P3 in the first direction Z. For example, the cold plate P3 rotationally moves between the first position T1 and the second position T2.

For example, as illustrated in FIG. 21, the cold plate P3 extends in parallel with the second direction X at the first position T1. When the cold plate P3 rotates about the inflow pipe 110B as a rotation axis, the cold plate P3 moves to the second position T2 illustrated in FIG. 22. The cold plate P3 extends obliquely with respect to the second direction X at the second position T2.

As described above, the distance between the cold plate P3 and the heat generating component 503 increases or decreases in the first direction Z in accordance with the rotation of the cold plate P3. In other words, the cold plate P3 is movable in the first direction Z with respect to the heat generating component 503. This facilitates the operation of disposing the heat generating component 503, and improves the contact accuracy of the cold plate P3 with the heat generating component 503.

As illustrated in FIG. 20, elastic portions D5 and D6 are provided on the inflow pipe 110B. More specifically, the elastic portions D5 and D6 are located between the inflow pipe 110B and the inside of the pipe portion 125A of the fifth connection portion 125. The elastic portions D5 and D6 are O-rings, packings, gaskets, or the like similar to the elastic portions D1 to D4. In the example illustrated in FIG. 20, the elastic portions D5 and D6 are O-rings. The outer diameter of the O-ring is, for example, substantially the same as the width of the inside of the pipe portion 125A. The inner diameter of the O-ring is, for example, substantially the same as the outer diameter of the inflow pipe 110B. In the example illustrated in FIG. 20, the elastic portions D5 and D6 are arranged with a predetermined distance along the third direction Y, but the number and positions of the elastic portions arranged on the inflow pipe 110B are not limited to the example illustrated in FIG. 20.

By disposing the elastic portions D5 and D6 between the inflow pipe 110B and the inside of the pipe portion 125A of the fifth connection portion 125 in this manner, the space between the inflow pipe 110B and the inside of the pipe portion 125A of the fifth connection portion 125 can be more reliably closed, and the refrigerant can be prevented from leaking out of the cold plate P3.

The relationship between the inflow pipe 110B and the fifth connection portion 125 may be reversed. That is, the pipe portion 125A of the fifth connection portion 125 may be disposed inside the inflow pipe 110B. In that case, the elastic portions D5 and D6 are provided on the pipe portion 125A.

The sixth connection portion 126 and the outflow pipe 120B may have the same structures as those of the fifth connection portion 125 and the inflow pipe 110B, respectively. Furthermore, not limited to the eighth connection portion 128, the inflow pipe 110B may be connected to the seventh connection portion 127 so as to be rotatable in the circumferential direction. That is, it is sufficient that the cold plate P3 is rotatable with respect to one of the fifth connection portion 125 and the seventh connection portion 127 and one of the sixth connection portion 126 and the eighth connection portion 128.

The example embodiments (including modifications) of the present disclosure have been described above with reference to the drawings. However, the present disclosure is not limited to the above-described example embodiments, and can be implemented in various modes without departing from the gist thereof. Various disclosures can be formed by appropriately combining the plurality of components disclosed in the above example embodiments. For example, some components may be removed from all components illustrated in the example embodiments. For example, components described in different example embodiments may be appropriately combined. The components in the drawings are mainly and schematically illustrated for facilitating better understanding, and the thickness, length, number, interval, and the like of each illustrated component may be different from reality for the convenience of creating drawings. The material, shape, dimensions, and the like of each component described in the above example embodiments are merely examples and are not particularly limited, and various modifications can be made without substantially departing from the effects of the present disclosure.

For example, in the above example embodiment, the example has been described in which the heat generating component 500 includes the first heat generating component 501 and the second heat generating component 502, and the cold plate P1 and the cold plate P2 cool the first heat generating component 501 and the second heat generating component 502, respectively, but the present disclosure is not limited thereto. The heat generating component 500 may have one heat generating component. The cold plate P1 and the cold plate P2 may cool one heat generating component 500.

In the above example embodiment, an example in which the heat conductor 170 is located between the cold plate P1 and the heat generating component 500 has been described. However, the present disclosure is not limited to this, and the heat conductor 170 may not be disposed. That is, the contact surface 151 of the cold plate P1 may be brought into direct contact with the heat generating component 500.

Furthermore, for example, in the above-described example embodiments, an example in which the first connection portion 113, the branch portion 112, and the second connection portion 114 are arranged in a straight line has been described. That is, the example has been described in which the first connection portion 113, the branch portion 112, and the second connection portion 114 are located between the cold plate P1 and the cold plate P2 in the first direction Z, and the inflow pipe 110 is formed in a substantially T shape. However, the present disclosure is not limited thereto. For example, the branch portion 112 may be disposed outside a portion between the cold plate P1 and the cold plate P2 in the first direction Z to form the inflow pipe 110 in a substantially Y shape. Similarly, the merging portion 123 of the outflow pipe 120 may be disposed outside a portion between the cold plate P1 and the cold plate P2 in the first direction Z to form the outflow pipe 120 in a substantially Y shape.

The present technology can also adopt the following configurations.
(1) A cooling assembly including a first cold plate and a second cold plate provided on respective sides of a heat generating component in a first direction, an inflow pipe that allows a refrigerant to flow into the first cold plate and the second cold plate, and an outflow pipe through which the refrigerant flowing out of the first cold plate and the second cold plate passes, in which at least a portion of the first cold plate and at least a portion of the second cold plate overlap each other in the first direction, and at least a portion of the inflow pipe and at least a portion of the outflow pipe are located between the first cold plate and the second cold plate in the first direction.
(2) The cooling assembly according to (1), in which the inflow pipe includes a common inflow portion, a branch portion that branches the refrigerant passing through the common inflow portion, a first connection portion connecting the branch portion and the first cold plate, and a second connection portion connecting the branch portion and the second cold plate, and the outflow pipe includes a third connection portion connected to the first cold plate, a fourth connection portion connected to the second cold plate, a merging portion that merges the refrigerant passing through the third connection portion and the refrigerant passing through the fourth connection portion, and a common outflow portion through which the refrigerant having passed through the merging portion passes.
(3) The cooling assembly according to (1) or (2), in which the first cold plate includes a contact surface in contact with the heat generating component, an internal flow path that overlaps the contact surface in the first direction and through which the refrigerant passes, and a fin assembly in the internal flow path and including a plurality of fins, the cooling assembly further includes a heat conductor located between the contact surface and the heat generating component, and the heat conductor and the fin assembly overlap each other in the first direction.
(4) The cooling assembly according to (3), in which the first cold plate further includes a partition in the internal flow path and partitioning the internal flow path into a plurality of flow paths, the plurality of fins is arranged in a second direction orthogonal to the first direction, and the partition is adjacent to the fin assembly in a third direction orthogonal to the first direction and the second direction.
(5) The cooling assembly according to (4), in which the first cold plate includes a first member and a second member defining the internal flow path, the fin assembly is provided on the first member, and the partition is provided on the second member.
(6) A cooling system including the cooling assembly according to any one of (1) to (5), a pump assembly that causes the refrigerant to flow through the cooling assembly, and a heat exchanger that cools the refrigerant flowing from the cooling assembly, in which the cooling assembly, the pump assembly, and the heat exchanger are connected to each other by a connection pipe, and the refrigerant circulates through the cooling assembly, the pump assembly, and the heat exchanger.
(7) The cooling assembly according to (1), in which the second cold plate is movable with respect to the first cold plate.
(8) The cooling assembly according to (7), in which the inflow pipe includes a common inflow portion, a branch portion that branches the refrigerant passing through the common inflow portion, a first connection portion connecting the branch portion and the first cold plate, and a second connection portion connecting the branch portion and the second cold plate, the outflow pipe includes a third connection portion connected to the first cold plate, a fourth connection portion connected to the second cold plate, a merging portion that merges the refrigerant passing through the third connection portion and the refrigerant passing through the fourth connection portion, and a common outflow portion through which the refrigerant having passed through the merging portion passes, the first connection portion, the second connection portion, the third connection portion, and the fourth connection portion extend along the first direction, an inflow port of the first connection portion is disposed inside the second connection portion, or an inflow port of the second connection portion is disposed inside the first connection portion, and an outflow port of the third connection portion is disposed inside the fourth connection portion, or an outflow portion of the fourth connection portion is disposed inside the third connection portion.
(9) The cooling assembly according to (8), in which an elastic portion is located between the inflow port of the first connection portion and the inside of the second connection portion, or between the inflow port of the second connection portion and the inside of the first connection portion, and an elastic portion is located between the outflow port of the third connection portion and the inside of the fourth connection portion, or between the outflow port of the fourth connection portion and the inside of the third connection portion.
(10) The cooling assembly according to (8) or (9), in which the first cold plate, the first connection portion, and the third connection portion are defined by a single monolithic portion, and the second cold plate, the second connection portion, and the fourth connection portion are defined by a single monolithic portion.
(11) The cooling assembly according to any one of (8) to (10), in which the first connection portion and the second connection portion are provided on one side of the first cold plate in the second direction, and the third connection portion and the fourth connection portion are provided on one side of the second cold plate in the second direction.
(12) The cooling assembly according to any one of (8) to (11), in which the first connection portion and the second connection portion are provided on one side of the first cold plate in the third direction, and the third connection portion and the fourth connection portion are provided on one side of the second cold plate in the third direction.
(13) A cooling assembly including: a third cold plate provided on one side of a heat generating component in a first direction, an inflow pipe that allows a refrigerant to flow into the third cold plate, an outflow pipe through which the refrigerant flowing out of the third cold plate passes, a fifth connection portion connected to an end on one side of the inflow pipe and fixed to the third cold plate, and a sixth connection portion connected to an end on one side of the outflow pipe and fixed to the third cold plate, in which an end on another side of the inflow pipe is connected to a seventh connection portion, an end on another side of the outflow pipe is connected to an eighth connection portion, and the third cold plate is movable with respect to the seventh connection portion and the eighth connection portion.
(14) The cooling assembly according to (13), in which the outflow pipe and the fifth connection portion extend along a third direction orthogonal to the first direction, and the outflow pipe is disposed inside the fifth connection portion.
(15) The cooling assembly according to (13) or (14), in which an elastic portion is located between the outflow pipe and an inside of the fifth connection portion.

Example embodiments of the present disclosure are applicable to cooling assemblies and cooling systems.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

1-15. (canceled)

16: A cooling assembly comprising:
a first cold plate and a second cold plate provided on respective sides of a heat generating component in a first direction;
an inflow pipe that allows a refrigerant to flow into the first cold plate and the second cold plate; and
an outflow pipe through which the refrigerant flowing out of the first cold plate and the second cold plate passes; wherein at least a portion of the first cold plate and at least a portion of the second cold plate overlap each other in the first direction; and
at least a portion of the inflow pipe and at least a portion of the outflow pipe are located between the first cold plate and the second cold plate in the first direction.

17: The cooling assembly according to claim 16, wherein
the inflow pipe includes:
a common inflow portion;
a branch portion that branches the refrigerant passing through the common inflow portion;
a first connection portion connecting the branch portion and the first cold plate; and
a second connection portion connecting the branch portion and the second cold plate; and
the outflow pipe includes:
a third connection portion connected to the first cold plate;
a fourth connection portion connected to the second cold plate;
a merging portion that merges the refrigerant passing through the third connection portion and the refrigerant passing through the fourth connection portion; and
a common outflow portion through which the refrigerant having passed through the merging portion passes.

18: The cooling assembly according to claim 16, wherein
the first cold plate includes:
a contact surface in contact with the heat generating component;
an internal flow path that is disposed to overlap the contact surface in the first direction and through which the refrigerant passes; and
a fin assembly located in the internal flow path and including a plurality of fins;
the cooling assembly further includes a heat conductor located between the contact surface and the heat generating component; and
the heat conductor and the fin assembly overlap each other in the first direction.

19: The cooling assembly according to claim 18, wherein
the first cold plate further includes a partition located in the internal flow path and partitioning the internal flow path into a plurality of flow paths;
the plurality of fins is arranged in a second direction orthogonal to the first direction; and
the partition is adjacent to the fin assembly in a third direction orthogonal to the first direction and the second direction.

20: The cooling assembly according to claim 19, wherein
the first cold plate includes a first member and a second member defining the internal flow path;
the fin assembly is provided on the first member; and
the partition is provided on the second member.

21: A cooling system comprising:
the cooling assembly according to claim 16;
a pump assembly that causes the refrigerant to flow through the cooling assembly; and
a heat exchanger that cools the refrigerant flowing from the cooling assembly; wherein
the cooling assembly, the pump assembly, and the heat exchanger are connected to each other by a connection pipe; and
the refrigerant circulates through the cooling assembly, the pump assembly, and the heat exchanger.

22: The cooling assembly according to claim 16, wherein the second cold plate is movable with respect to the first cold plate.

23: The cooling assembly according to claim 22, wherein
the inflow pipe includes:
a common inflow portion;
a branch portion that branches the refrigerant passing through the common inflow portion;
a first connection portion connecting the branch portion and the first cold plate; and
a second connection portion connecting the branch portion and the second cold plate;
the outflow pipe includes:
a third connection portion connected to the first cold plate;
a fourth connection portion connected to the second cold plate;
a merging portion that merges the refrigerant passing through the third connection portion and the refrigerant passing through the fourth connection portion; and
a common outflow portion through which the refrigerant having passed through the merging portion passes;
the first connection portion, the second connection portion, the third connection portion, and the fourth connection portion extend along the first direction;
an inflow port of the first connection portion is located inside the second connection portion, or an inflow port of the second connection portion is located inside the first connection portion; and
an outflow port of the third connection portion is located inside the fourth connection portion, or an outflow port of the fourth connection portion is located inside the third connection portion.

24: The cooling assembly according to claim 23, wherein
an elastic portion is located between the inflow port of the first connection portion and the inside of the second connection portion, or between the inflow port of the second connection portion and the inside of the first connection portion; and
an elastic portion is located between the outflow port of the third connection portion and the inside of the fourth connection portion, or between the outflow port of the fourth connection portion and the inside of the third connection portion.

25: The cooling assembly according to claim 23, wherein
the first cold plate, the first connection portion, and the third connection portion are defined by a single monolithic portion; and
the second cold plate, the second connection portion, and the fourth connection portion are defined by a single monolithic portion.

26: The cooling assembly according to claim 23, wherein
the first connection portion and the second connection portion are provided on one side of the first cold plate in the second direction; and
the third connection portion and the fourth connection portion are provided on one side of the second cold plate in the second direction.

27: The cooling assembly according to claim 26, wherein
the first connection portion and the second connection portion are provided on one side of the first cold plate in the third direction; and
the third connection portion and the fourth connection portion are provided on one side of the second cold plate in the third direction.

28: A cooling assembly comprising:
a third cold plate provided on one side of a heat generating component in a first direction;
an inflow pipe that allows a refrigerant to flow into the third cold plate;
an outflow pipe through which the refrigerant flowing out of the third cold plate passes;
a fifth connection portion connected to an end on one side of the inflow pipe and fixed to the third cold plate; and
a sixth connection portion connected to an end on one side of the outflow pipe and fixed to the third cold plate; wherein
an end on another side of the inflow pipe is connected to a seventh connection portion;
an end on another side of the outflow pipe is connected to an eighth connection portion; and
the third cold plate is movable with respect to the seventh connection portion and the eighth connection portion.

29: The cooling assembly according to claim 28, wherein
the inflow pipe and the fifth connection portion extend along a third direction orthogonal to the first direction; and
the inflow pipe is located inside the fifth connection portion.

30: The cooling assembly according to claim 29, wherein an elastic portion is located between the inflow pipe and an inside of the fifth connection portion.
